(19) United States
(12) Patent Application Publication
(10) Pub. No.: US 2017/0009332 A1
(43) Pub. Date: Jan. 12, 2017

(54) SMALL MASK TILING FOR LARGER AREA DEPOSITIONS

(71) Applicant: Advantech Global, Ltd, Tortola (VG)

(72) Inventors: Brian Authur Bucci, Pittsburgh, PA (US); Scott Aaron Lauer, Cabot, PA (US)

(21) Appl. No.: 15/121,858

(22) PCT Filed: Mar. 6, 2015
(86) PCT No.: PCT/US2015/019122

§ 371 Date: Aug. 26, 2016

Related U.S. Application Data
(60) Provisional application No. 61/951,728, filed on Mar. 12, 2014.

(51) Int. Cl. C23C 14/04

(52) U.S. Cl. CPC C23C 14/042

(57) ABSTRACT

In a method of physical vapor deposition (PVD), a first arrangement of material patterns can be deposited on different parts of a substrate in the same deposition chamber or vessel via a first number of shadow masks, or one pattern at a time can be deposited on different parts of the substrate using the same shadow mask. A second arrangement of material patterns can be deposited on different parts of the substrate in another deposition chamber or vessel via a second number of shadow masks. The each material pattern of the second arrangement of material patterns are deposited so as to not overlap a material pattern of the first arrangement of material patterns.

### CROSS REFERENCE TO RELATED APPLICATION

This application claims the benefit of U.S. Provisional Application No. 61/951,728, filed Mar. 12, 2014, which is incorporated herein by reference.

### BACKGROUND OF THE INVENTION

Field of the Invention

The present invention relates to physical vapor deposition of material on a substrate via a shadow mask and, more particularly, to using one or more small shadow masks to tile multiple instances of the same pattern or different patterns on a single larger area substrate.

Description of Related Art

Heretofore, a single shadow mask and a single target (or material deposition source) disposed in a deposition chamber or vessel was utilized to physical vapor deposit (PVD) material from the target onto a substrate via the shadow mask. It has been observed that as the size of the shadow mask increases, the positions of apertures across the dimensions of the shadow mask become subject to runout error, which is a stackup of accumulated errors in the positioning of apertures and/or holes in the shadow mask, due to the inability to maintain tight tolerances in the positioning of such apertures and/or holes in the shadow mask over the dimensions of the shadow mask.

Accordingly, it would be desirable to use one or more smaller shadow masks to produce a number of patterns on a larger area substrate.

### SUMMARY OF THE INVENTION

Disclosed herein is a physical vapor deposition (PVD) method. The method comprises: (a) providing a deposition vessel having therein a substrate, a shadow mask including an aperture pattern, and a plurality of material deposition sources in different locations of the deposition vessel, wherein, in plan view, the shadow mask is smaller in area than the substrate; (b) positioning the shadow mask in the deposition vessel between a first one of the plurality of material deposition sources and a first part of the substrate; (c) following step (b), depositing material from the first one of the plurality of material deposition sources on the first part of the substrate via the aperture pattern of the shadow mask; (d) following step (c), repositioning the shadow mask in the deposition vessel between another one of the plurality of material deposition sources and another part of the substrate; and (e) following step (d), depositing material from the other one of the plurality of material deposition sources on the other part of the substrate via the aperture pattern of the shadow mask.

The method can include: (f) repeating steps (d) and (e) at least once for a different part of the substrate.

The material deposition sources can be charged with the same material or with different materials.

A frame can support the shadow mask in the deposition vessel. A motion stage can position the shadow mask on the frame in step (b) and can reposition the shadow mask on the frame in step (d).

Also disclosed is a physical vapor deposition (PVD) method in a deposition vessel including a plurality of material deposition sources, a substrate and a shadow mask. The method comprises: (a) PVD depositing a first material from a first of the plurality of material deposition sources on a first part of a substrate via the shadow mask positioned between the first material deposition source and the first part of the substrate; (b) following step (a), repositioning the shadow mask between another of the plurality of material deposition sources and another part of a substrate; and (c) following step (b), PVD depositing a material from the other material deposition source on the other part of a substrate via the shadow mask.

The method can include repeating steps (b)-(c) at least once.

At least some of the material deposition sources can be charged with the same material or with different materials.

A motion stage can be provided for repositioning the shadow mask in step (b).

Also disclosed is a physical vapor deposition (PVD) method comprising: (a) providing first and second deposition chambers having respective first and second inverse 2-dimensional arrangements of material deposition sources therein, wherein like locations in the first and second deposition chambers include respectively a material deposition source and no material deposition source, or vice versa; (b) providing in the first deposition chamber a first array of shadow masks in the same arrangement as the material deposition sources in the first deposition chamber; (c) providing in the second deposition chamber a second array of shadow masks in the same arrangement as the material deposition sources in the second deposition chamber; (d) depositing on a substrate via the first array of shadow masks first patterns of materials from the first arrangement of material deposition sources; and (e) depositing on the substrate via the second array of shadow masks second patterns of materials from the second arrangement of material deposition sources.

Each pattern of the first and second patterns of materials can be the same. Each pattern of the first and second patterns of materials can have the same x, y orientation on the substrate.

The material deposition sources in each deposition chamber can be arranged in columns (C) and rows (R). The first deposition chamber can have material deposition sources at C1, R1 and C2, R2, and no material deposition sources at C1, R2 and C2, R1. The second deposition chamber can have material deposition sources at C1, R2 and C2, R1, and no material deposition sources at C1, R1 and C2, R2.

The shadow masks of each array of shadow masks can be arranged in columns (C) and rows (R). The first array of shadow masks can have shadow masks at C1, R1 and C2, R2, and no shadow masks at C1, R2 and C2, R1. The second array of shadow masks can have shadow masks at C1, R2 and C2, R1, and no shadow masks at C1, R1 and C2, R2.

Adjacent at least one side of each shadow mask can be a space that is at least the area of the shadow mask. Such spaces can be adjacent two sides of the shadow mask.

At least portions of the first and second patterns of materials can be interleaved.

Finally, disclosed herein is a physical vapor deposition (PVD) method comprising: (a) in a first deposition vessel, PVD depositing materials from a plurality of first material deposition sources in a first arrangement on a substrate via a first set of shadow masks positioned between the plurality of first material deposition source and the substrate; and (b) in a second deposition vessel, PVD depositing materials from a plurality of second material deposition sources in a second, inverse arrangement on the substrate via a second set of shadow masks positioned between the plurality of second material deposition sources and the substrate.

The first arrangement can include a first plurality of patterns of deposited materials. The second arrangement can include a second plurality of patterns of deposited materials. Each pattern can be the same. Each pattern can have the same orientation on the substrate.

At least some of the deposition sources can be charged with the same material or with different materials.

### BRIEF DESCRIPTION OF THE DRAWINGS

FIG. 1 is a schematic illustration of a physical vapor deposition (PVD) system including a number of targets or material deposition sources and a shadow mask that is moveable via a motion stage to a number of different positions within the deposition vessel between each target and a substrate to receive a deposit of the materials from each target;

FIGS. 2A-2D are views of the four targets taken along lines II-II in FIG. 1 showing (via concentric circles) which target is active at a particular time;

FIGS. 3A-3D are views of different positions of a shadow mask on a frame corresponding to the targets which are active in FIGS. 2A-2D respectively;

FIGS. 4A-4D show sections of a substrate that receive a deposit of material in response to the positions of the shadow masks and the activations of the targets shown in FIGS. 3A-3D and FIGS. 2A-2D, respectively;

FIG. 5A is a schematic illustration of another PVD system including first and second deposition chambers or vessels, with each deposition chamber including a number of targets or material deposition sources and a like number of shadow masks for producing a tiled arrangement of material deposition patterns on a substrate moving through the deposition chambers, wherein a first part of the substrate is aligned to receive a first material deposition pattern by the passage of materials from the material deposition sources through apertures of the shadow masks of the first deposition chamber;

FIG. 5B is a plan view of a substrate showing the first material deposition pattern that can be formed on a first part of the substrate in the first deposition chamber;

FIGS. 6A and 6B show arrangements of the material deposition sources and the shadow masks taken along lines VIA-VIA, and VIB-VIB, respectively, of the first deposition chamber of FIG. 5A;

FIGS. 7A and 7B show arrangements of the material deposition sources and the shadow masks taken along lines VIIA-VIIA, and VIIB-VIIB, respectively, in the second deposition chamber of FIG. 5A;

FIG. 8A shows the PVD system of FIG. 5A with a second part of the substrate aligned to receive a second material deposition pattern in the first deposition chamber;

FIG. 8B shows the combination of the first material deposition pattern and the second material deposition pattern produced on the first and second parts of the substrate in the first deposition chamber;

FIG. 9A shows the PVD system of FIG. 8A with the first part of the substrate positioned in the second deposition chamber and aligned to receive a third material deposition pattern by the passage of materials from the material deposition sources through apertures of the shadow masks of the second deposition chamber;

FIG. 9B shows the combination of the first, second, and third material deposition patterns produced on the first and second parts of the substrate in the first and second deposition chambers;

FIG. 10A shows the PVD system of FIG. 9A with the second part of the substrate aligned to receive a fourth material deposition pattern in the second deposition chamber; and

FIG. 10B shows the combination of the first, second, third, and fourth material deposition patterns produced on the first and second parts of the substrate in the first and second deposition chambers.

### DETAILED DESCRIPTION OF THE INVENTION

The present invention will be described with reference to the accompanying figures where like reference numbers correspond to like elements.

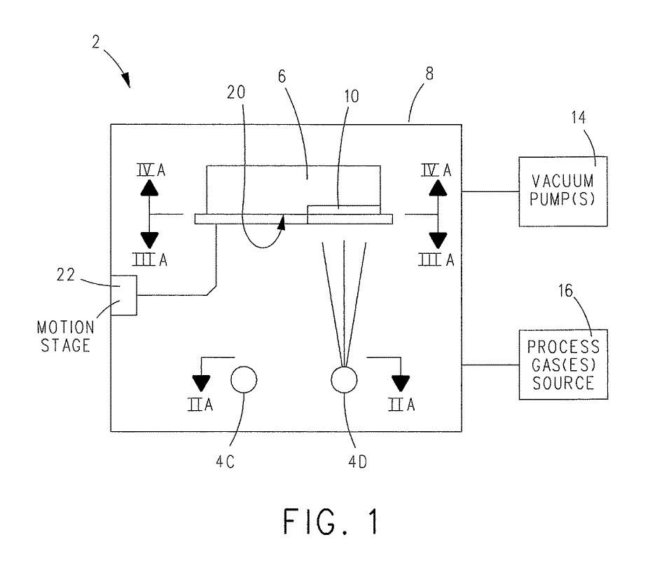

With reference to FIGS. 1-4D, an exemplary physical vapor deposition (PVD) system 2 includes a plurality of targets 4A-4D, each of which is comprised of a solid or liquid target material, and a deposition substrate 6 positioned to receive deposits of target material ejected or evaporated from targets 4A-4D, positioned in spaced relation to each other inside of a deposition chamber or deposition vessel 8. A shadow mask 10 is positioned closely adjacent or in intimate contact with substrate 6 between substrate 6 and targets 4A-4D via a frame 12.

One or more vacuum pumps 14 can be connected to deposition chamber 8 for reducing the pressure within deposition chamber 8 to a desirable pressure for depositing material from targets 4A-4D onto substrate 6 via shadow mask 10 in the manner described hereinafter. A process gases source 16 can be coupled to deposition chamber for introducing one or more suitable process gases into deposition chamber 8 to facilitate the controlled deposition of material from targets 4A-4D onto substrate 6 via one or more apertures 18 in shadow mask 10 in a manner described hereinafter.

Depending on the PVD method being utilized to deposit materials from targets 4A-4D onto substrate 6 via one or more apertures 18 in shadow mask 10 will determine whether vacuum pumps and process gases source 16 are optional or necessary. Exemplary PVD methods include, without limitation, sputtering, vapor phase deposition, cathodic arc deposition, electron beam physical vapor deposition, evaporative deposition, and pulse laser deposition. This list of possible PVD deposition methods, however, is not to be construed as limiting the invention.

An exemplary shadow mask 10 positioned adjacent or in intimate contact with substrate 6 includes a plurality of apertures 18 where target material from targets 4A-4D pass through for deposit on a surface 20 of substrate 6 exposed via said apertures 18 and in a pattern defined by said apertures 18.

A motion stage 22 can be provided that is operative for moving or repositioning shadow mask 10 in the manner described hereinafter.

The use of PVD system 2 to deposit multiple instances of the same pattern on substrate 6 utilizing a single shadow mask 10 in deposition chamber 8 will now be described.

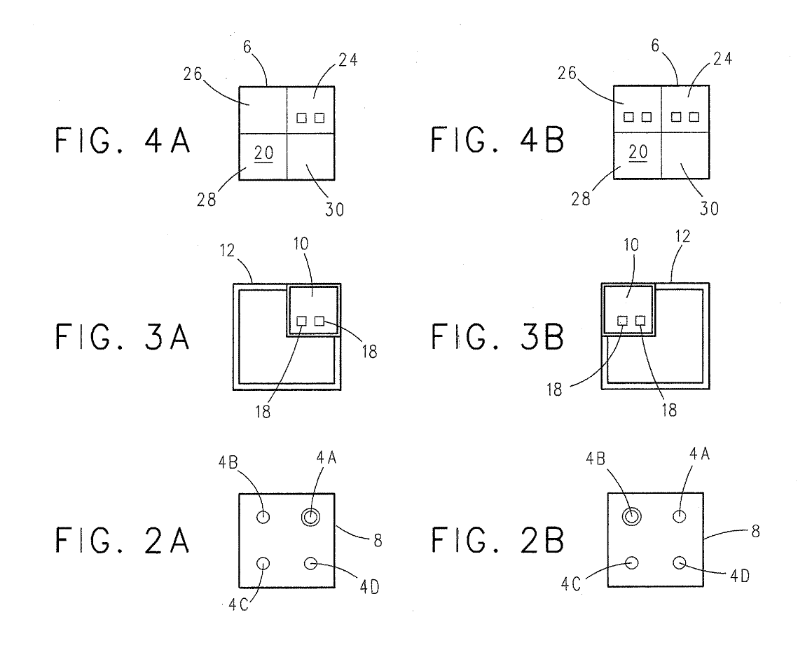

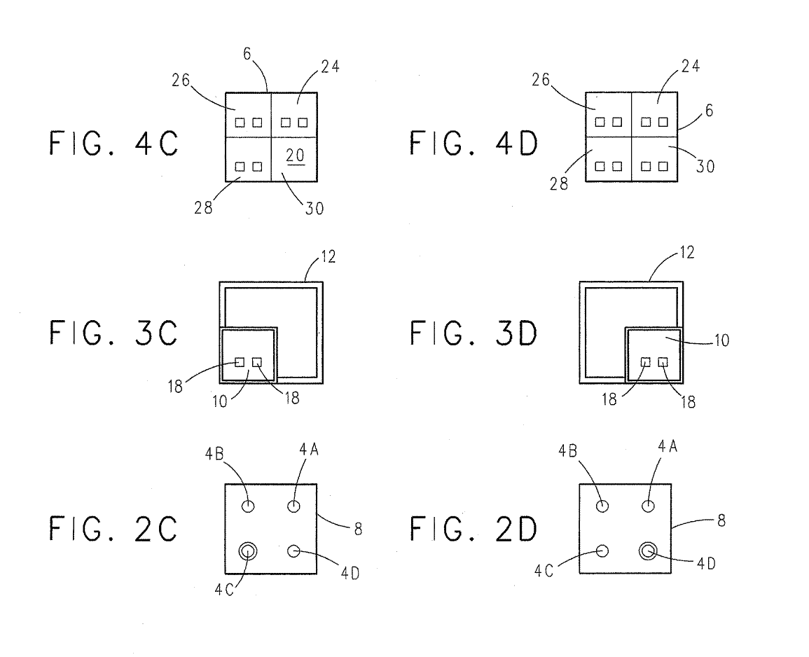

With specific reference to FIGS. 2A, 3A, and 4A, with shadow mask 10 positioned between target 4A and substrate 20, target 4A is cause to eject or evaporate material therefrom onto a first portion 24 of surface 20 of substrate 6 via apertures 18 in shadow mask 10. When a sufficient amount of material has been deposited on first portion 24 of surface 20 of substrate 6, the ejection or evaporation of material from target 4A is terminated.

Referring now to FIGS. 2B, 3B, and 4B, next, via motion stage 22, shadow mask 10 is moved to a position between target 4B and the second portion 26 of surface 20 of substrate 6. Thereafter, target 4B is caused to eject or evaporate material therefrom onto the second portion 26 of surface 20 of substrate 6 via apertures 18 in shadow mask 10. When sufficient material has been deposited from target 4B onto second portion 26 of surface 20 of substrate 6, the ejection or evaporation of material from target 4B is terminated.

With reference to FIGS. 2C, 3C, and 4C, next, via motion stage 22, shadow mask 10 is moved to a position between target 4C and a third portion 28 of surface 20 of substrate 6. Thereafter, material is ejected or evaporated from target 4C onto the third portion 28 of surface 20 of substrate 6 via apertures 18 in shadow mask 10. When a sufficient amount of material from target 4C has been deposited on the third portion 28 of surface 20 of substrate 6, the ejection or evaporation of material from target 4C is terminated.

With reference to FIGS. 2D, 3D, and 4D, finally, via motion stage 22, shadow mask 10 is moved to a position between target 4D and a fourth portion 30 of surface 20 of substrate 6. Thereafter, material is ejected or evaporated from target 4D onto the fourth portion 30 of surface 20 of substrate 6 via apertures 18 in shadow mask 10. When a sufficient amount of material from target 4D has been deposited on fourth portion 30 of surface 20 of substrate 6, the ejection or evaporation of material from target 4D is terminated. In an example, targets 4A-4D can be made from the same material, different materials, or combinations of the same and different materials. For example, targets 4A and 4B can be formed from one material, target 4C can be formed from another material, and target 4D can be formed from yet another material.

Upon completion of the deposition events on portions 24, 26, 28, and 30 of surface 20 of substrate 6, substrate 6 can be removed from deposition chamber 8 for further processing. Alternatively, shadow mask 10 can be replaced with another shadow mask (not shown) having a different pattern of apertures. This other shadow mask 10 can then be moved between portions 24, 26, 28, and 30 to facilitate deposition of materials from targets 4A-4D, which can be charged with the same or different materials than the material(s) utilized to produce the patterns in portions 24, 26, 28, and 30 of surface 20 via shadow mask 10 in the manner discussed above.

The use of a single mask and four targets to produce four separate instances of the same pattern on portions 24, 26, 28, and 30 of surface 20, however, is not to be construed as limiting the invention since it is envisioned that any number of targets 4 can be selected and shadow mask 10 can be configured in any suitable and/or desirable manner that facilitates any number of instances of the same pattern on surface 20.

As can be seen in the example shown in FIGS. 1-4D, a single shadow mask 10 that is smaller in area than substrate 6 can be utilized to tile or produce a number of instances of the same pattern on the surface 20 of substrate 6. To this end, for each deposition event on a different portion of substrate 20, shadow mask 10 is moved between said portion and a target 4 whereupon material from target 4 is PVD deposited on said portion of surface 20 via shadow mask 10. Thereafter, for each instance of a deposition event on a different portion of substrate 6, shadow mask 10 is moved into alignment between said portion and a different target to be used to deposit the material on said portion of said substrate.

As can be seen, disclosed is a PVD method that includes positioning shadow mask 10 in deposition vessel 8 between a first target (or material deposition source) 4A and a first portion 24 of substrate 6. Material from target 4A is then deposited on the first portion 24 of substrate 6 via the aperture pattern 18 of shadow mask 10.

Shadow mask 10 is then repositioned in the deposition vessel 8 between another one of the targets (or material deposition sources) 4B and another portion 26 of substrate 6. Material from target 4B is then deposited on portion 26 of substrate 6 via the aperture pattern 18 of shadow mask 10.

This process can be repeated at least once more for a different combination of substrate portion 28 or 30 of substrate 6 and target (or material deposition source) 4C or 4D.

The material deposition sources can be charged with the same material or the material deposition sources can be charged with different materials.

In another example, the method includes PVD depositing a first material from target 4A on a first part 24 of substrate 6 via shadow mask 10 positioned between target 4A and said first part 24. Thereafter, shadow mask 10 is repositioned between another target, e.g., target 4B, and another part of the substrate, e.g., part 26 of substrate 6. Next, material from the other target (4B) is PVD deposited on the other part (26) of the substrate via shadow mask 10.

The steps of repositioning the shadow mask between another of the plurality of material of deposition sources and another part of the substrate and PVD depositing the material from the other material deposition source onto the other part of the substrate via the shadow mask can be repeated one or more times as deemed necessary and/or desirable.

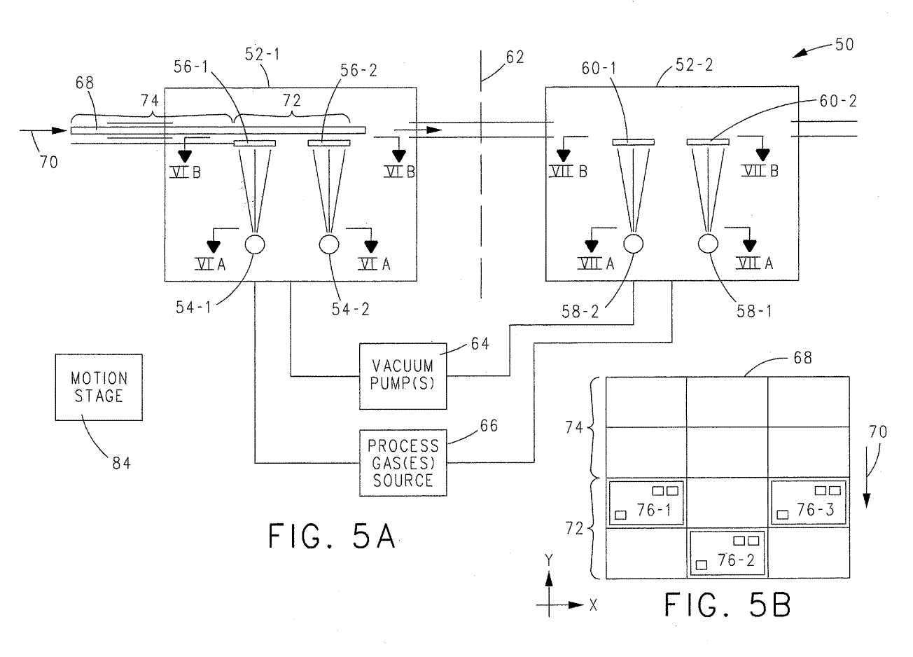

With reference to FIGS. 5A-7B, another example PVD system 50 includes first and second deposition chambers or vessels 52-1 and 52-2. Deposition chamber 52-1 includes a first plurality, set or arrangement of targets (or material deposition sources) 54-1, 54-2, and 54-3. Deposition chamber 54-1 also includes a first plurality, set or arrangement of shadow masks 56-1, 56-2, and 56-3 having the same physical arrangement as targets 54-1, 54-2, and 54-3, respectively.

Deposition chamber 54-2 includes a second plurality, set or arrangement of targets (or material deposition sources) 58-1, 58-2, and 58-3. Deposition chamber 52-2 also includes a second plurality, set or arrangement of shadow masks 60-1, 60-2, and 60-3 in the same physical arrangement as targets 58-1, 58-2, and 58-3.

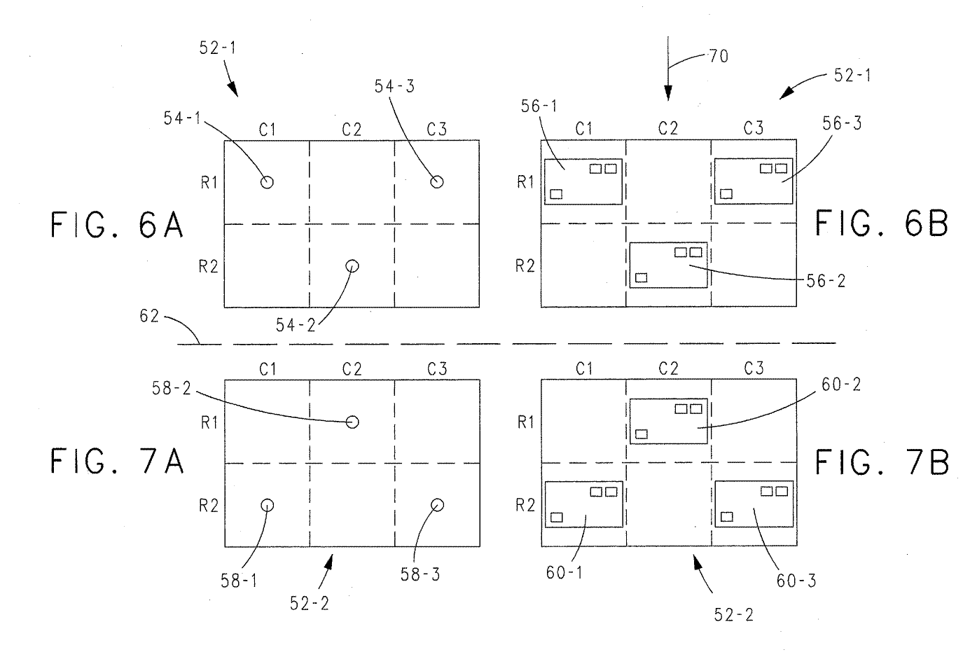

As can be seen by comparing FIGS. 6A and 7A, the arrangement of material deposition sources 58-1, 58-2, and 58-3 in deposition chamber 52-2 is the inverse or mirror image about dashed line 62 of the arrangement of material depositions sources 54-1, 54-2, and 54-3 in deposition chamber 52-1. In an example, the material deposition sources 54 and 58 in deposition chambers 52-1 and 52-2 are arranged into rows (R) and columns (C), with material deposition sources 54-1, 54-2, and 54-3 of deposition chamber 52-1 populating C1, R1; C2, R2; and C3, R1. In contrast, material deposition sources 58-1, 58-2, and 58-3 in deposition chamber 52-2 populate C1, R2; C2, R1; and C3, R2, respectively.

Similarly, the shadow masks in each deposition chamber are arranged into columns (C) and rows (R), with the arrangement of shadow masks 60-1, 60-2, and 60-3 in deposition chamber 52-2 being the inverse or mirror image about dashed line 62 of the arrangement of shadow masks 56-1, 56-2, and 56-3 in deposition chamber 52-1. In an example, in FIG. 6A, shadow masks 56-1, 56-2, and 56-3 of deposition chamber 52-1 populate C1, R1; C2, R2; and C3, R1; and no shadow masks are included in C1, R2; C2, R1; or C3, R2. Similarly, shadow masks 60-1, 60-2, and 60-3 of deposition chamber 52-2 populate C1, R2; C2, R1; and C3, R2; and no shadow masks are included in C1, R1; C2, R2; or C3, R1.

Comparing FIGS. 6A and 7A, it can be seen that like rows and columns in deposition chambers 52-1 and 52-2 include respectively a material deposition source and no material deposition source, or vice versa. For example, C1, R1 in deposition chamber 52-1 includes material deposition source 54-1 while C1, R1 of deposition chamber 52-2 does not include a material deposition source. Moreover, C1, R2 in deposition chamber 52-1 does not include a material deposition source while C1, R2 in deposition chamber 52-2 includes material deposition source 58-1. Similar comments apply for the other columns and rows of deposition chambers 52-1 and 52-2.

Similarly, comparing FIGS. 6B and 7B, it can be seen that C1, R1 of deposition chamber 52-1 includes shadow mask 56-1 while C1, R1 of deposition chamber 52-2 does not include a shadow mask. Similarly, C1, R2 of deposition chamber 52-1 does not include a shadow mask while C1, R2 of deposition chamber 52-2 includes shadow mask 60-1. Similar comments apply in respect of the other columns and rows in deposition chambers 52-1 and 52-2 including respectively a shadow mask or no shadow mask, or vice versa.

One or more vacuum pumps 64 can be connected to deposition chambers 52-1 and 52-2 for reducing the pressure therein to a desirable pressure for depositing material from material deposition sources 54-1, 54-2, and 54-3 of deposition chamber 52-1 and from material deposition sources 58-1, 58-2, and 58-3 of deposition chamber 52-2 onto a substrate 66 in the manner described hereinafter. A process gas(es) source 64 can be coupled to deposition chambers 52-1 and 52-2 for introducing one or more suitable process gases into deposition chambers 52-1 and 52-2 to facilitate the controlled deposition of material from the material deposition sources of deposition chambers 52-1 and 52-2 onto substrate 66 via the shadow masks 56 and 60 in each deposition chamber.

Depending on the PVD method being utilized to deposit material from material deposition sources 54 and 56 onto substrate 6 via one or more apertures in the various shadow masks 56 and 60 will determine whether vacuum pumps 64 and process gases source 66 are optional or necessary.

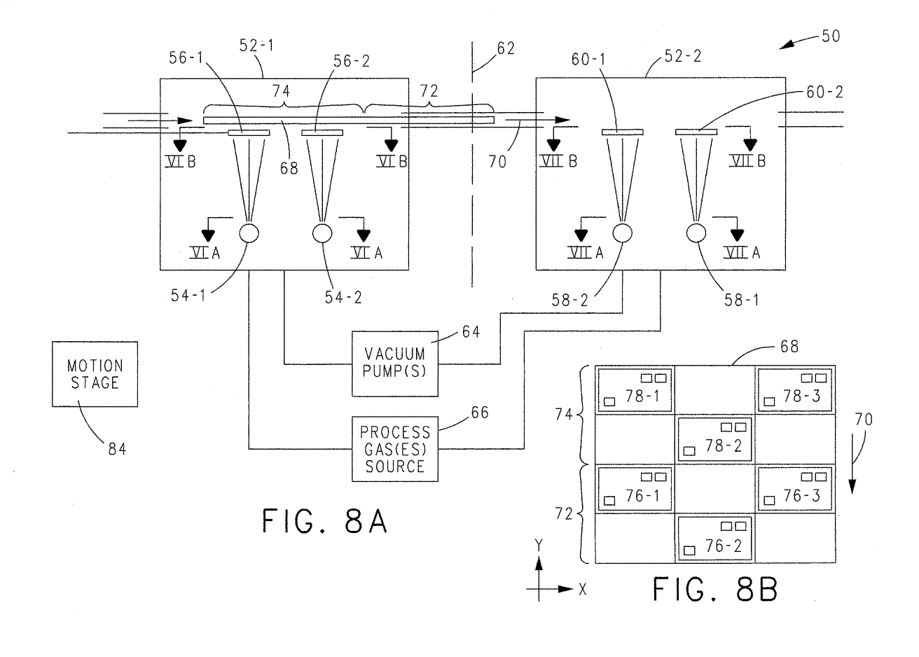

Having described PVD system 50, a method of using PVD system 50 to deposit patterns on substrate 68 will now be described with reference to FIGS. 8A-10B with continuing reference to FIGS. 5A-7B.

At a suitable time, substrate 68 is introduced into deposition chamber 52-1 in a direction shown by arrow 70 until a first part 72 of substrate 68 is aligned over material deposition sources 54-1, 54-2, and 54-3, and shadow mask 56-1, 56-2 and 56-3 as shown in FIG. 5A. Thereafter, materials from material deposition sources 54-1, 54-2, and 54-3 are deposited on substrate 68 in a first material deposition pattern 76-1, 76-2, and 76-3 (FIG. 5B) via shadow masks 56-1, 56-2, and 56-3, respectively. It should be appreciated that material deposition pattern 76-1 is formed by the passage of material from material deposition source 54-1 through apertures (not numbered) in shadow mask 56-1. Similarly, material deposition pattern 76-2 is formed by the passage of material from material deposition source 54-2 through apertures (not numbered) in shadow mask 56-2, and material deposition pattern 76-3 is formed by the passage of material from material deposition source 54-3 through apertures (not numbered) in shadow mask 56-3.

Next, substrate 68 is advanced in the direction of arrow 70 until a second part 74 of substrate 68 is aligned over shadow mask 56-1, 56-2, and 56-3 in deposition chamber 54-1 as shown in FIG. 8A. Then, a second material deposition pattern 78-1, 78-2, and 78-3 is formed on the second part 74 of substrate 68 by the passage of materials from material deposition sources 54-1, 54-2, and 54-3 through apertures (not numbered) in shadow mask 56-1, 56-2, and 56-3, respectively. The combination of the first material deposition pattern 76-1, 76-2, and 76-3, and the second material deposition pattern 78-1, 78-2, and 78-3 on the first and second parts 72, 74 of substrate 68 are shown in FIG. 8B.

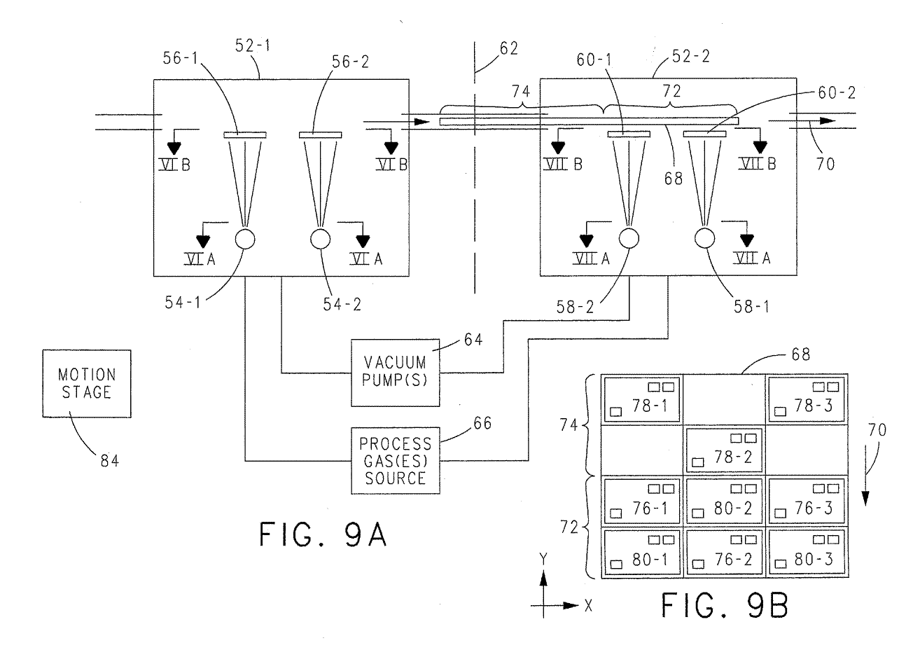

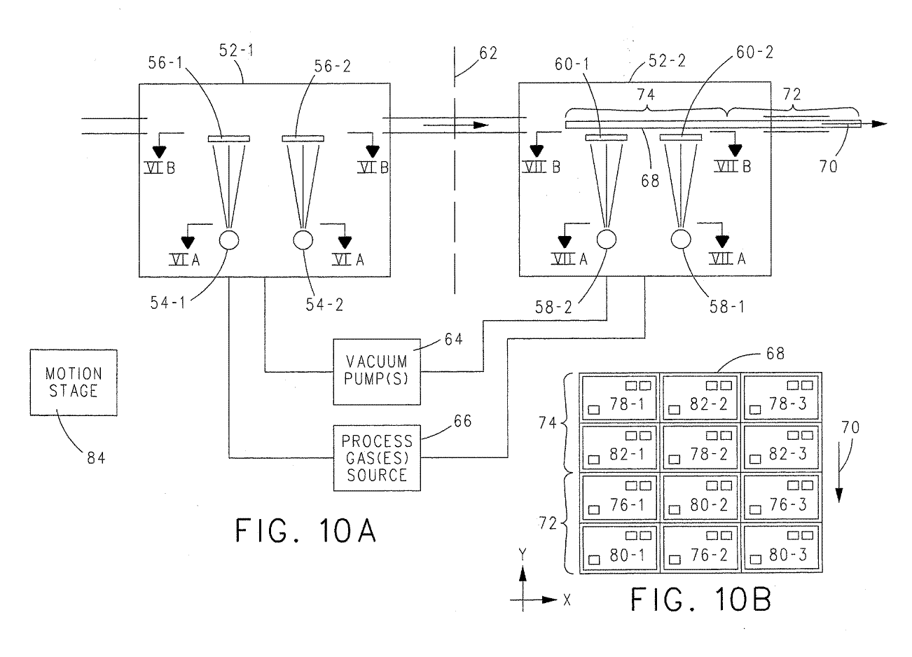

Next, substrate 68 is advanced in the direction of arrow 70 until the first part 72 of substrate 68 is aligned over shadow masks 60-1, 60-2, and 60-3 in deposition chamber 54-2 as shown in FIG. 9A. Then, a third material deposition pattern 80-1, 80-2, and 80-3 is formed on the first part 72 of substrate 68 by the passage of materials from material deposition sources 58-1, 58-2, and 58-3 through apertures (not numbered) in shadow mask 60-1, 60-2, and 60-3, respectively.

FIG. 9B shows the combination of the first, second and third material deposition patterns 76, 78, and 80 on substrate 68. As can be seen, the third material deposition patterns 80-1, 80-2, and 80-3 are deposited in the gaps or spaces adjacent to or between first material deposition patterns 76-1, 76-2, and 76-3.

Next, substrate 68 is advanced in the direction of arrow 70 until second part 74 of substrate 68 is aligned over shadow masks 60-1, 60-2, and 60-3 in deposition chamber 52-2 as shown in FIG. 10A. Then, fourth material deposition patterns 82-1, 82-2, and 82-3 are formed on the second part 74 of substrate 68 by the passage of materials from material deposition sources 58-1, 58-2, and 58-3 through apertures (not numbered) in shadow masks 60-1, 60-2, and 60-3, respectively.

FIG. 10B shows the combination of first, second, third, and fourth material deposition patterns 76, 78, 80, and 82 on substrate 68. As can be seen, fourth material deposition patterns 82-1, 82-2, and 82-3 are formed in the gaps or spaces adjacent to or between second material deposition patterns 78-1, 78-2, and 78-3.

As can be seen, by way of a tiled array of material deposition sources and a tiled array of shadow masks, a tiled array of material deposition patterns can be formed on substrate 68. In an example, the pattern of each material deposition pattern 76, 78, 80, and 82 is the same (as shown best in FIG. 10B). For example, deposition pattern 80-1 is the same as deposition pattern 76-1 which is the same as deposition pattern 82-1 which is the same as deposition pattern 78-1. Alternatively, different material deposition patterns can be formed on substrate 68 in the manner described above. For example, material deposition patterns 76 and 78 can be one pattern while material deposition patterns 80 and 82 can be another pattern. Still further, each material deposition pattern 76, 78, 80, and 82 can be different.

In the foregoing example, a single substrate 68 was illustrated. However, it is envisioned that substrate 68 can be a continuous substrate that extends through deposition chambers 52-1 and 52-2.

In an example, the passage of substrate 68 through deposition chambers 52-1 and 52-2 can be controlled by a suitable motion stage 84.

Each material deposition pattern 76, 78, 80, and 82 can be formed one material deposition pattern at a time or all of the material deposition patterns at a time. For example, when forming the first material deposition pattern 76-1, 76-2, and 76-3, material deposition sources 54-1, 54-2, and 54-3 can be activated to eject or evaporate target material all at the same time. Alternatively, each material deposition source 54-1, 54-2, and 54-3 can be activated one at a time. Still further, the activation of one material deposition source 54-2 can overlap the activation of another material deposition source 54-1.

As can be seen, PVD system 50 includes first and second deposition chambers 52-1 and 52-2 having respective first and second inverse two-dimensional arrangements of material deposition sources 54-1, 54-2, and 54-3, and 58-1, 58-2, and 58-3 therein. Like locations in the first and second deposition chambers 52-1 and 52-2 include, respectively, a material deposition source and no material deposition source, or vice versa.

As shown in FIGS. 6A-6B, first deposition chamber 52-1 includes a first array of shadow masks 56-1, 56-2, and 56-3 in the same physical arrangement as material deposition sources 54-1, 54-2, and 54-3, respectively. As shown in FIGS. 7A-7B second deposition chamber 52-2 includes a second array of shadow masks 60-1, 60-2, and 60-3 in the same physical arrangement as material deposition sources 58-1, 58-2, and 58-3. Via the first arrangement of material deposition sources 54-1, 54-2, and 54-3, first patterns of materials are deposited on substrate 68 via the first array of shadow masks 56-1, 56-2, and 56-3. Via the second arrangement of material deposition sources 58-1, 58-2, and 58-3, second patterns of material are deposited on substrate 68 via the second array of shadow masks 60-1, 60-2, and 60-3.

In an example, each pattern of the first and second patterns of materials can be the same. In this regard, each pattern of the first and second patterns of materials can have the same x, y orientation on substrate 68 as shown, e.g., in FIG. 10B, where each pattern (e.g., 76-1, 78-1, 80-1, 82-1) has two boxes in the upper right corner and a single box in the lower left corner.

As shown in FIGS. 6A and 7A, the material deposition sources in each deposition chamber 52-1 and 52-2 are arranged in columns (C) and rows (R). The first deposition chamber 52-1 has material deposition sources 54 at C1, R1; C2, R2; and C3, R1, and no material deposition sources at C1, R2; C2, R1; and C3, R.2. The second deposition chamber 52-2 has material deposition sources 58 at C1, R2; C2, R1; and C3, R2, and no material deposition sources at C1, R1; C2, R2; and C3, R1.

Similarly, the shadow masks of each array of shadow masks 56 and 60 are arranged in columns and rows. The first array of shadow masks 56 in deposition chamber 52-1 includes shadow masks at C1, R1; C2, R2; and C3, R1, and no shadow masks at C1, R2; C2, R1; and C3, R2. The second array of shadow masks 60 in deposition chamber 52-2 includes shadow masks at C1, R2; C2, R1; and C3, R2, and no shadow masks at C1, R1; C2, R2; and C3, R1.

As can be seen in FIGS. 6A and 6B, adjacent at least one side of each shadow mask 56 and 60 is a space that is at least the area of the shadow mask. In an example, spaces are adjacent two sides of each shadow mask. As can be seen in FIG. 10B, at least portions of patterns of materials deposited on substrate 68 are interleaved.

Another, more general, example of a PVD method includes: in a first deposition vessel, PVD depositing materials from a plurality of first material deposition sources 54 in a first arrangement 76 on substrate 68 via a first set of shadow masks 56 positioned between the plurality of first material deposition sources 54 and the substrate 68. In a second vessel, materials are PVD deposited from a plurality of second material deposition sources 58 in a second, inverse arrangement 80 on substrate 68 via a second set of shadow masks 60 positioned between the plurality of second material deposition sources 58 and substrate 68.

In an example, the first arrangement 76 includes a first plurality of patterns of deposited materials, e.g., 76-1, 76-2, and 76-3. The second arrangement 80 includes a second plurality of patterns of deposited materials, e.g., 80-1, 80-2, and 80-3.

Each pattern 76-1, 76-2, 76-3, 80-1, 80-2, and 80-3 can be the same or different. Where each pattern is the same, each pattern can have the same x, y orientation on substrate 68.

In an example, each material deposition source in each deposition chamber can be charged with the same material, or different material deposition sources in each deposition chamber can be charged with different materials. Combinations of material deposition sources in each deposition chamber being charged with the same material or with different materials are also envisioned.

The present invention has been described with reference to the accompanying figures. Obvious modifications and alterations will occur to others upon reading and understanding the preceding detailed description. The foregoing processes of tiling multiple patterns on a common substrate may be known by other names such as, without limitation, modular masking utilizing a number of modular masks; cellular masking utilizing a number of cellular masks; stitched masking utilizing a number of stitched masks; and/or other like terminologies. It is intended that the invention be construed as including all such modifications and alterations insofar as they come within the scope of the appended claims or the equivalents thereof.

The invention claimed is:

1. A physical vapor deposition (PVD) method comprising:
(a) providing a deposition vessel having therein a substrate, a shadow mask including an aperture pattern, and a plurality of material deposition sources in different locations of the deposition vessel, wherein, in plan view, the shadow mask is smaller in area than the substrate;
(b) positioning the shadow mask in the deposition vessel between a first one of the plurality of material deposition sources and a first part of the substrate;
(c) following step (b), depositing material from the first one of the plurality of material deposition sources on the first part of the substrate via the aperture pattern of the shadow mask;
(d) following step (c), repositioning the shadow mask in the deposition vessel between another one of the plurality of material deposition sources and another part of the substrate; and
(e) following step (d), depositing material from the other one of the plurality of material deposition sources on the other part of the substrate via the aperture pattern of the shadow mask.

2. The method of claim 1, further including:
(f) repeating steps (d) and (e) at least once for one different part of the substrate

3. The method of claim 1, wherein the material deposition sources are charged with the same material.

4. The method of claim 1, wherein the material deposition sources are charged with different materials.

5. The method of claim 1, wherein:
a frame supports the shadow mask in the deposition vessel; and
a motion stage positions the shadow mask on the frame in step (b) and repositions the shadow mask on the frame in step (d).

6. A physical vapor deposition (PVD) method in a deposition vessel including a plurality of material deposition sources, a substrate and a shadow mask, the method comprising:
(a) PVD depositing a first material from a first of the plurality of material deposition sources on a first part of a substrate via the shadow mask positioned between the first material deposition source and the first part of the substrate;
(b) following step (a), repositioning the shadow mask between another of the plurality of material deposition sources and another part of a substrate; and
(c) following step (b), PVD depositing a material from the other material deposition source on the other part of a substrate via the shadow mask.

7. The method of claim 6, further including repeating steps (b)-(c) at least once.

8. The method of claim 6, wherein at least some of the material deposition sources are charged with the same material.

9. The method of claim 6, wherein at least some of the material deposition sources are charged with different materials.

10. The method of claim 6, further including a motion stage for repositioning the shadow mask in step (b).

11. A physical vapor deposition (PVD) method comprising:
(a) providing first and second deposition chambers having respective first and second inverse 2-dimensional arrangements of material deposition sources therein, wherein like locations in the first and second deposition chambers include respectively a material deposition source and no material deposition source, or vice versa;
(b) providing in the first deposition chamber a first array of shadow masks in the same arrangement as the material deposition sources in the first deposition chamber;
(c) providing in the second deposition chamber a second array of shadow masks in the same arrangement as the material deposition sources in the second deposition chamber;
(d) depositing on a substrate via the first array of shadow masks first patterns of materials from the first arrangement of material deposition sources; and
(e) depositing on the substrate via the second array of shadow masks second patterns of materials from the second arrangement of material deposition sources.

12. The method of claim 11, wherein:
each pattern of the first and second patterns of materials are the same; and
each pattern of the first and second patterns of materials have the same x, y orientation on the substrate.

13. The method of claim 11, wherein:
the material deposition sources in each deposition chamber are arranged in columns (C) and rows (R);
the first deposition chamber has material deposition sources at C1, R1 and C2, R2, and no material deposition sources at C1, R2 and C2, R1; and
the second deposition chamber has material deposition sources at C1, R2 and C2, R1, and no material deposition sources at C1, R1 and C2, R2.

14. The method of claim 11, wherein:
the shadow masks of each array of shadow masks are arranged in columns (C) and rows (R);
the first array of shadow masks has shadow masks at C1, R1 and C2, R2, and no shadow masks at C1, R2 and C2, R1; and
the second array of shadow masks has shadow masks at C1, R2 and C2, R1, and no shadow masks at C1, R1 and C2, R2.

15. The method of claim 11, wherein adjacent at least one side of each shadow mask is a space that is at least the area of the shadow mask.

16. The method of claim 15, wherein spaces are adjacent two sides of the shadow mask.

17. The method of claim 11, wherein at least portions of the first and second patterns of materials are interleaved.

18. A physical vapor deposition (PVD) method comprising:
(a) in a first deposition vessel, PVD depositing materials from a plurality of first material deposition sources in a first arrangement on a substrate via a first set of shadow masks positioned between the plurality of first material deposition source and the substrate; and
(b) in a second deposition vessel, PVD depositing materials from a plurality of second material deposition sources in a second, inverse arrangement on the substrate via a second set of shadow masks positioned between the plurality of second material deposition sources and the substrate.

19. The method of claim 18, wherein:
the first arrangement includes a first plurality of patterns of deposited materials;
the second arrangement includes a second plurality of patterns of deposited materials;
each pattern is the same; and
each pattern has the same orientation on the substrate.

20. The method of claim 18, wherein at least some of the deposition sources are charged with the same material or with different materials.
